(19) United States
(12) Patent Application Publication
(10) Pub. No.: US 2009/0130813 A1
(43) Pub. Date: May 21, 2009

(54) Method and System to Provide a Polysilicon Capacitor with Improved Oxide Integrity

(75) Inventor: Arthur Lam, Fremont, CA (US)

Correspondence Address: SAWYER LAW GROUP LLP, 2465 E. Bayshore Road, Suite No. 406, PALO ALTO, CA, 94303, US

(73) Assignee: Micrel, Inc., San Jose, CA (US)

(21) Appl. No.: 11/942,895

(22) Filed: Nov. 20, 2007

(51) Int. Cl. H01L 21/20

(52) U.S. Cl. 438/381; 257/E21.008

(57) ABSTRACT

A system and method in accordance with the present invention allows for an improved oxide integrity of a polysilicon capacitor compared to capacitors manufactured using conventional semiconductor processing techniques. This is accomplished by moving the capacitor implant step to a time after the deposition of the polysilicon. As an additional benefit, a separate capacitor oxide growth does not need to be performed.

### FIELD OF THE INVENTION

The present invention relates generally to integrated circuits and more particularly to polysilicon capacitors utilized in such circuits.

### BACKGROUND OF THE INVENTION

Polysilicon capacitors are used on integrated circuits (ICs) or discrete devices as storage devices. These types of capacitors to operate properly must have little or no change in capacitance when varying the voltage across the capacitor. This is referred to as the capacitance vs. voltage characteristic. Typically, this characteristic is provided by heavily doping both plates the capacitor. The polysilicon capacitor includes a bottom plate which is heavily doped with boron. A dielectric is then provided that is a grown oxide or an oxynitride or a combination of alternating films of oxide and nitride. A top plate of the capacitor is composed of polysilicon which is doped either through an implant or a gas such as POCI3 or BBR3, or a heavily doped glass. To restrict the heavily doped boron to the bottom plate, a mask is used to define the bottom plate area.

There are many ways to fabricate this capacitor. Typically the boron is implanted into silicon through a temporary or sacrificial implant oxide that is defined by an implant mask which defines the bottom plate of the capacitor. Due to contamination from the resist and due to the need to grow a gate ox different parts of the IC, this oxide is removed and a permanent capacitor oxide is grown, at the same time that the gate oxide is grown. Since the bottom plate is heavily doped with boron, boron gets incorporated into the capacitor oxide during the oxidation. Also due to the high doping level, metallic impurities from the manufacturing process are incorporated into the heavily doped bottom plate. During the oxidation, the metals are also incorporated into the capacitor oxide. The incorporation of these impurities into the capacitor oxide results in degraded capacitor oxide quality. This degradation may not be screened out during the testing of the part. The integrated circuit, believed to be fully functional, will be incorporated into a system. This degradation eventually results in the rupture of the capacitor oxide. Accordingly the oxide integrity, ie capacitor vs. voltage characteristic, of the capacitor is adversely affected and the integrated circuit fails to operate as designed. The failure of the integrated circuit to operate, once incorporated into a system is a reliability hazard.

Accordingly, what is desired is a system and method for providing a polysilicon capacitor that has improved reliability over conventional polysilicon capacitors. The present invention addresses such a need.

### SUMMARY OF THE INVENTION

A system and method in accordance with the present invention allows for an improved oxide integrity of a polysilicon capacitor compared to capacitors manufactured using conventional semiconductor processing techniques. This is accomplished by moving the capacitor implant step to a time after the deposition of the polysilicon. As an additional benefit, a separate capacitor oxide growth does not need to be performed.

### BRIEF DESCRIPTION OF THE DRAWINGS

FIGS. 1 and 2a-2e illustrate a process for providing a polysilicon capacitor in accordance with a conventional process and its resulting structure, respectively.

FIGS. 3, 4a, 4b, and 5 illustrate a process for providing a polysilicon capacitor in accordance with a process of the present invention and its resulting structure.

### DETAILED DESCRIPTION

The present invention relates generally to integrated circuits and more particularly to polysilicon capacitors utilized in such circuits. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

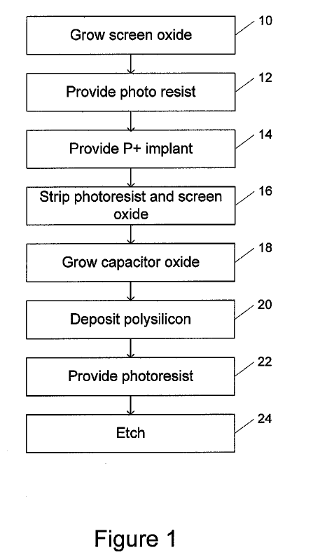

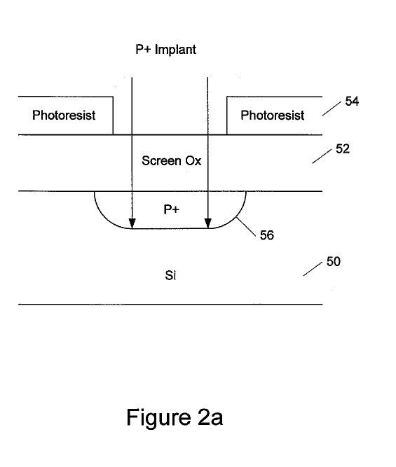

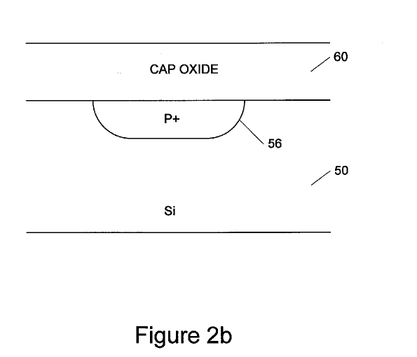

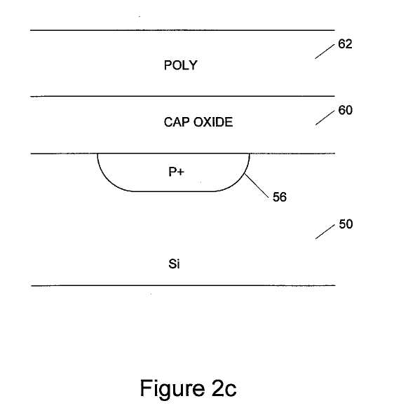

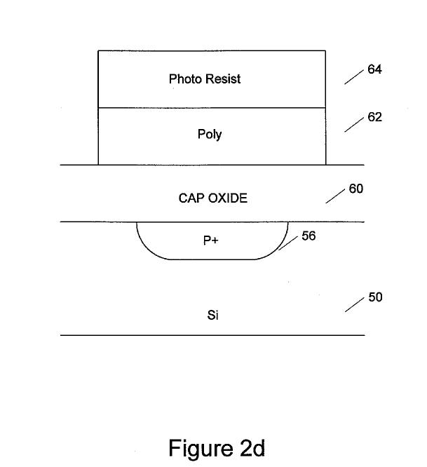

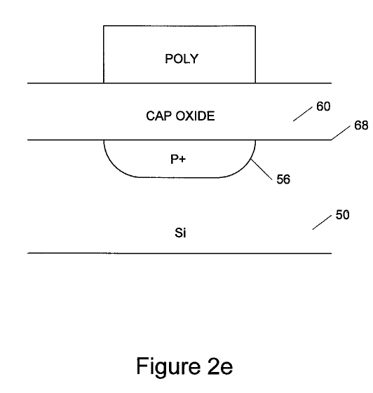

FIGS. 1 and 2a-2e illustrate a process for providing a polysilicon capacitor in accordance with a conventional process and its resulting structure, respectively. Referring to FIGS. 1a and 2a-2e together, in the conventional process, a screen oxide layer 52 is grown over a silicon substrate 50, via step 10 and a photoresist 54 is provided over the screen oxide layer 52 except over the area upon which a P+ implant is to be provided, via step 12. (FIG. 2a). Next, the P+ implant is provided, via step 14 and a heavily doped P+ region 56 is provided in the silicon substrate 50 under the screen oxide layer 52. Next the photoresist 54 and the screen oxide layer 52 are stripped off of the silicon substrate 50, via step 16. Thereafter, a capacitor oxide layer 60 is grown over the doped region 56 of the silicon substrate 50, via step 18 (FIG. 2b). Then polysilicon 62 is deposited on the capacitor oxide layer 60, via step 20 (FIG. 2c). Thereafter, a photoresist 64 is provided over the capacitor area of the polysilicon 62, via step 22 and the area is etched to provide the polysilicon capacitor, via step 24 (FIG. 2d).

The implanting of the p+ dopant causes the interface 68 between the oxide 60 (shown in FIG. 2e) and the doped region 56 to change based upon incorporation of impurities due to the oxidation of silicon during the capacitor oxide growth. Impurities composed of metals such as iron (Fe) or nickel (Ni), can be incorporated into the p+ region due to a gettering mechanism. Furthermore these impurities can migrate onto the capacitor oxide 60 during the capacitor oxide growth through the interface 68. These two actions can significantly affect the capacitance to voltage characteristic of the capacitor.

A system and method in accordance with the present invention minimizes the change to the interface between the oxide and the doped region and also minimizes the incorporation of metallic impurities by moving the implant step to a time after the deposition of the polysilicon or eliminating the implant step altogether. In so doing, an oxide quality is achieved that is equivalent to the gate oxide quality. As an additional benefit, a separate capacitor implant oxide step does not need to be performed.

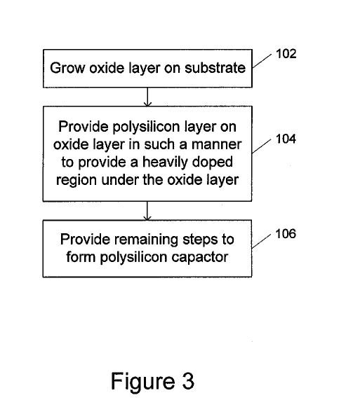

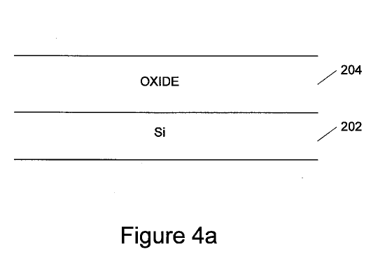

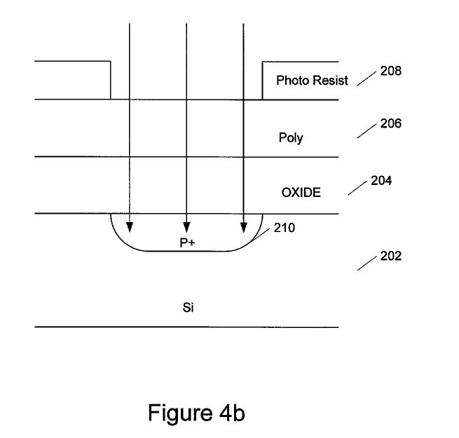

FIGS. 3, 4a, 4b, and 5 illustrate a process for providing a polysilicon capacitor in accordance with a process of the present invention and its resulting structure. An embodiment of a polysilicon capacitor is disclosed in the present application. One of ordinary skill in the art readily recognizes, however, the process can be utilized in any type of device and that use would be in the spirit and scope of the present invention. Referring to FIGS. 3, 4a and 4b together, first, an oxide layer 204 is grown on a silicon substrate 202 (FIG. 4a), via step 102. In one embodiment, the oxide layer 204 is a gate oxide layer typically associated with semiconductor processing. Next, a polysilicon layer is provided on the oxide layer in such a manner that a heavily doped P+ region is provided under the oxide layer such that the capacitance vs. voltage characteristic is minimally affected, via step 104. Thereafter appropriate processing steps are utilized to later provide the remaining portions of the polysilicon capacitor, via step 106 to provide the same structure as shown in FIG. 2e.

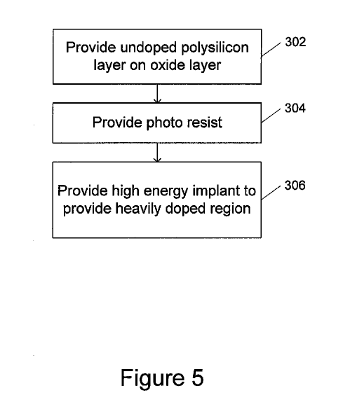

The providing step 104 can be accomplished in a variety of ways depending on the technology. FIG. 5 illustrates one embodiment of providing the polysilicon layer in accordance with step 104. In this embodiment, an undoped polysilicon layer 206 is provided on the oxide layer 204, via step 302. Then a photoresist 208 is provided over the appropriate portion of the polysilicon layer 206, via step 304 and a high energy implant is provided thereafter to provide the heavily doped P+ region 210 in the silicon substrate 202 under the oxide layer (FIG. 4b), via step 306. By providing the high energy implant after the poly deposition the problems associated with the impurities due to oxidation of the silicon are substantially reduced. Doping of the polysilicon is accomplished by implanting the poly, either by an implant chosen specifically for this purpose or by a source-drain implant and the appropriate use of photoresist.

In a second embodiment for example a doped polysilicon is deposited on the gate oxide to provide the heavily doped region. In this embodiment, the remaining steps to form the polysilicon capacitor are as described in 106. In a third embodiment, a gas such as POCI3 or BBR3 could be utilized in a heavy dose on the undoped polysilicon layer to provide a heavily doped region therewith. The remaining steps to form the polysilicon capacitor are as described in 106. It is understood that the energy for implanting dopant or that the gas levels the gas levels utilized for providing the highly doped region would be higher than that required using the conventional process to penetrate the polysilicon and leave the peak of the dopant near the surface. For example, the energy required for the implant might be 160 Kev vs. 50 KeV required for the implant for the conventional process of FIG. 1. A fourth embodiment would use a dielectric composed of a combination of grown and deposited films, for example, oxide and deposited nitride and a grown oxide over the nitride. A fifth embodiment would use a film, such as an anti-reflective layer or hard mask) on top of the polysilicon.

### CONCLUSION

A system and method in accordance with the present invention allows for an improved capacitor vs. voltage characteristic of a polysilicon capacitor compared to capacitors manufactured using conventional semiconductor processing techniques. This is accomplished by moving the capacitor implant step to a time after the deposition of the polysilicon. As an additional benefit, a separate capacitor oxide growth does not need to be performed.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A method for providing a polysilicon capacitor comprising:
providing an oxide layer over a silicon substrate;
providing a polysilicon layer over the oxide layer such that a heavily doped region is later provided such that the oxide integrity is minimally affected and providing appropriate processing steps to provide the polysilicon capacitor.

2. The method of claim 1 wherein the polysilicon layer providing step comprises:
providing an undoped polysilicon layer over the oxide layer;
providing a photo resist over the appropriate portion of the undoped polysilicon layer; and
providing a high energy implant to provide a highly doped region under the oxide layer.

3. The method of claim 1 wherein the polysilicon layer providing step comprises depositing a doped polysilicon on the gate oxide to provide the heavily doped region thereunder.

4. The method of claim 1 wherein the polysilicon layer providing step comprises:
providing an undoped polysilicon layer over the oxide layer; and
utilizing a gas for the undoped polysilicon layer to provide a heavily doped region thereunder.

5. The method of claim 1 wherein the polysilicon layer providing step comprises:
providing an undoped polysilicon layer over the oxide layer; and
implanting the undoped polysilicon layer to provide a heavily doped region thereunder.

6. The method of claim 1 wherein the polysilicon layer has a film over it for hard mask or Anti-Reflective Layer.

7. The method of claim 1 wherein the oxide layer comprises a gate oxide layer.

8. The method of claim 1 wherein the dielectric layer comprises a combination of deposited and grown layers.

9. The method of claim 1 wherein the heavily doped region comprises a P+ region.

10. The method of claim 1 wherein the dopant comprises Boron.

11. The method of claim 1 wherein the gases utilized comprises any of Phosphorous Oxychloride (POCI₃) and BBr₃.

12. A method for providing a P+ Polysilicon capacitor comprising:
providing a gate oxide layer over a silicon substrate;
providing an undoped polysilicon layer over the gate oxide layer;
providing a photo resist over the appropriate portion of the undoped polysilicon layer; and
providing an energy implant after providing the undoped polysilicon layer to provide a P+ region heavily doped with Boron within the silicon substrate and underneath the gate oxide layer.
